(19) United States
(12) Patent Application Publication
(10) Pub. No.: US 2021/0234048 A1
(43) Pub. Date: Jul. 29, 2021

(54) THIN-FILM TRANSISTOR AND MANUFACTURING METHOD THEREFOR

(71) Applicant: SAKAI DISPLAY PRODUCTS CORPORATION, Sakai-shi, Osaka (JP)

(72) Inventors: HIROYUKI OHTA, Sakai-shi, Osaka (JP); TOMOHIRO INOUE, Sakai-shi, Osaka (JP); KOTA IMANISHI, Sakai-shi, Osaka (JP); YOSHIAKI MATSUSHIMA, Sakai-shi, Osaka (JP); RYOHEI TAKAKURA, Sakai-shi, Osaka (JP)

(21) Appl. No.: 15/734,927

(22) PCT Filed: Jun. 7, 2018
(86) PCT No.: PCT/JP2018/021919

§ 371 Date: Dec. 3, 2020

(51) Int. Cl. H01L 29/786; H01L 29/66

(52) U.S. Cl. CPC H01L 29/78618; H01L 29/78663; H01L 29/78672; H01L 29/6675

(57) ABSTRACT

A thin film transistor (101) includes: a gate electrode (2) supported by a substrate (1); a gate insulating layer (3) covering the gate electrode; a semiconductor layer (4) being disposed on the gate insulating layer and including a polysilicon region (4p), the polysilicon region (4p) including a first region (Rs), a second region (Rd), and a channel region (Rc) that is located between the first region and the second region; a source electrode (8s) electrically connected to the first region; a drain electrode (8d) electrically connected to the second region; a protective insulating layer (5) disposed between the semiconductor layer and the source electrode and drain electrode; an i type semiconductor layer composed of an intrinsic semiconductor, the i type semiconductor layer being disposed between the protective insulating layer and the channel region so as to be directly in contact with a portion of the channel region; and a sidewall disposed on a side surface of the protective insulating layer. The i type semiconductor layer has a band gap larger than that of the polysilicon region. When viewed from a normal direction of the substrate, the sidewall is directly in contact with the channel region, between the i type semiconductor layer and the first region and between the i type semiconductor layer and the second region.

### TECHNICAL FIELD

The present invention relates to a thin film transistor and a method of producing the same.

### BACKGROUND ART

Thin film transistors (hereinafter, “TFT”) are used as switching elements on an active matrix substrate of a display apparatus such as a liquid crystal display apparatus or an organic EL display apparatus, for example. In the present specification, such TFTs will be referred to as “pixel TFTs”. As pixel TFTs, amorphous silicon TFTs whose active layer is an amorphous silicon film (hereinafter abbreviated as an “a-Si film”), polycrystalline silicon TFTs whose active layer is a polycrystalline silicon (polysilicon) film (hereinafter abbreviated as a “poly-Si film”), and the like have been widely used. Generally speaking, a poly-Si film has a higher field-effect mobility than that of an a-Si film, and therefore a polycrystalline silicon TFT has a higher current driving power (i.e., a larger ON current) than that of an amorphous silicon TFT.

A TFT having a gate electrode disposed at the substrate side of the active layer is referred to as a “bottom-gate type TFT”, whereas a TFT having a gate electrode disposed above its active layer (i.e., the opposite side from the substrate) is referred to as a “top-gate type TFT”. In some cases, forming bottom-gate type TFTs as the pixel TFTs may have cost advantages relative to forming top-gate type TFTs.

Known types of bottom-gate type TFTs are channel-etch type TFTs (hereinafter “CE-type TFT”) and etch-stop type TFTs (hereinafter “ES-type TFT”). In a CE-type TFT, an electrically conductive film is formed directly upon an active layer, and this electrically conductive film is patterned to provide a source electrode and a drain electrode (source-drain separation). On the other hand, in an ES-type TFT, a source-drain separation step is performed while a channel section of the active layer is covered with an insulating layer that functions as an etchstop (hereinafter referred to as a “protective insulating layer”).

Polycrystalline silicon TFTs are usually of top-gate type, but polycrystalline silicon TFTs of bottom-gate type have also been proposed. For example, Patent Document 1 discloses a polycrystalline silicon TFT of bottom-gate type (ES-type).

### CITATION LIST

### Patent Literature

[Patent Document 1] Japanese Laid-Open Patent Publication No. 6-151856

### SUMMARY OF INVENTION

### Technical Problem

As display apparatuses become larger in size and higher-definitioned, it is required to further enhance the channel mobility of TFTs and improve the ON characteristics thereof.

An embodiment of the present invention has been made in view of the above circumstances, and an objective thereof is to provide a thin film transistor of bottom-gate type that can have high ON characteristics and a method of producing the same.

### Solution to Problem

A thin film transistor according to an embodiment of the present invention comprises: a substrate; a gate electrode supported by the substrate; a gate insulating layer covering the gate electrode; a semiconductor layer being disposed on the gate insulating layer and including a polysilicon region, the polysilicon region including a first region, a second region, and a channel region that is located between the first region and the second region; a source electrode electrically connected to the first region; a drain electrode electrically connected to the second region; and a protecting section disposed between the semiconductor layer and the source electrode and drain electrode, the protecting section covering the channel region but not covering the first region and the second region, wherein the protecting section includes at least one i type semiconductor layer composed of an intrinsic semiconductor, the at least one i type semiconductor layer being disposed directly in contact with a portion of the channel region, a protective insulating layer disposed on the i type semiconductor layer, and a sidewall disposed on a side surface of the protective insulating layer; the i type semiconductor layer has a band gap larger than that of the polysilicon region; and, when viewed from a normal direction of the substrate, the sidewall is directly in contact with the channel region, between the i type semiconductor layer and the first region and between the i type semiconductor layer and the second region.

In one embodiment, when viewed from the normal direction of the substrate, the sidewall surrounds the i type semiconductor layer.

In one embodiment, the sidewall is disposed on the side surface of the protective insulating layer and a side surface of the i type semiconductor layer.

In one embodiment, when viewed from the normal direction of the substrate, a total area of portions of the channel region that are in contact with the i type semiconductor layer accounts for not less than 50% and not more than 90% of an area of the entire channel region.

In one embodiment, the source electrode is connected to the first region of the semiconductor layer via a first contact layer, and the drain electrode is connected to the second region of the semiconductor layer via a second contact layer; and the first and second contact layers each include an n⁺ type a-Si layer composed of an n⁺ type amorphous silicon.

In one embodiment, the i type semiconductor layer has an islanded structure including a plurality of i type semiconductor islets disposed in a discrete manner.

In one embodiment, when viewed from the normal direction of the substrate, the semiconductor layer further includes an amorphous silicon region located outside the polysilicon region.

In one embodiment, the i type semiconductor layer is an i type a-Si layer composed of an intrinsic amorphous silicon.

A display apparatus according to an embodiment of the present invention comprises the thin film transistor of any of the above, wherein the display apparatus has a displaying region including a plurality of pixels; and the thin film transistor is disposed in each of the plurality of pixels.

A method of producing a thin film transistor according to an embodiment of the present invention is a method of producing a thin film transistor supported by a substrate, the method comprising: a step of forming on the substrate a gate electrode, a gate insulating layer covering the gate electrode, and a semiconductor layer including a polysilicon region; a step of forming on the semiconductor layer an i type semiconductor film and a protective insulating film in this order, the i type semiconductor film being composed of an intrinsic semiconductor, wherein the i type semiconductor film has a band gap larger than that of the polysilicon region; a step of patterning the i type semiconductor film and the protective insulating film to form an i type semiconductor layer from the i type semiconductor film and to form a protective insulating layer from the protective insulating film, wherein the i type semiconductor layer and the protective insulating layer are located on a part of a portion of the semiconductor layer to become a channel, and expose a first region and a second region that are located on opposite sides of the portion of the semiconductor layer to become the channel region; a step of forming an insulating film covering the semiconductor layer, the i type semiconductor layer, and the protective insulating layer, and performing anisotropic etching to form a sidewall on a side surface of the protective insulating layer from the insulating film; a step of forming a silicon film for contact layer formation and an electrically conductive film in this order, so as to cover the semiconductor layer, the i type semiconductor layer, the protective insulating layer, and the sidewall; and an source-drain separation step of patterning the silicon film for contact layer formation and the electrically conductive film by using the protective insulating layer as an etchstop, to form from the silicon film for contact layer formation a first contact layer that is in contact with the first region and a second contact layer that is in contact with the second region, and to form from the electrically conductive film a source electrode that is in contact with the first contact layer and a drain electrode that is in contact with the second contact layer.

In one embodiment, the i type semiconductor film is formed by utilizing an initial phase of growth of film formation by a CVD technique.

In one embodiment, the i type semiconductor film has an islanded structure including a plurality of i type semiconductor islets disposed in a discrete manner.

In one embodiment, the i type semiconductor layer is an i type a-Si layer composed of an intrinsic amorphous silicon.

A method of producing a display apparatus according to an embodiment of the present invention is a method of producing a display apparatus comprising the thin film transistor of any of the above, wherein the display apparatus has a displaying region including a plurality of pixels, the thin film transistor being disposed in each of the plurality of pixels of the displaying region; the method of producing comprises a semiconductor layer forming step of forming the semiconductor layer of the thin film transistor; and the semiconductor layer forming step comprises a crystallization step of irradiating only a portion of a semiconductor film that is formed on the gate insulating layer and composed of an amorphous silicon with laser light to crystallize the portion of the semiconductor film, wherein the polysilicon region is formed in the portion of the semiconductor film while leaving a portion of the semiconductor film that has not been irradiated with the laser light so as to remain amorphous.

### Advantageous Effects of Invention

According to an embodiment of the present invention, there is provided a thin film transistor of bottom-gate type that can have high ON characteristics and a method of producing the same.

### BRIEF DESCRIPTION OF DRAWINGS

FIG. 1 (a) and (b) are a schematic plan view and a cross-sectional view, respectively, of a TFT 101 according to a first embodiment; (c) is an enlarged cross-sectional view of a channel section of the TFT 101; and (d) is an enlarged plan view showing an example arrangement of an i type a-Si layer 10 and a sidewall SW.

FIG. 2 An enlarged plan view illustrating another protecting section 20 for the TFT according to the first embodiment.

FIG. 3 (a) and (b) are an enlarged cross-sectional view and an enlarged plan view showing another protecting section 20 for the TFT according to the first embodiment.

FIG. 40 (a) to (j) are schematic step-by-step cross-sectional views for describing an example method of producing the TFT 101.

FIG. 5 (a) and (b) are a schematic plan view and a cross-sectional view, respectively, of a TFT 102 according to Embodiment for Reference; and (c) is an enlarged cross-sectional view of a channel section of the TFT 102.

FIG. 6 (a) to (d) are schematic step-by-step cross-sectional views for describing an example method of producing the TFT 102.

FIG. 70 (a) is an enlarged cross-sectional view schematically showing a thin film transistor according to Reference Example; and (b) to (d) are enlarged cross-sectional views schematically showing thin film transistors according to Comparative Examples 1 to 3, respectively.

FIG. 8 A diagram showing V-I characteristics of thin film transistors according to Reference Example and Comparative Examples.

FIG. 9 (a) and (b) are diagrams each showing an energy band structure near a junction interface between an i type a-Si layer and a poly-Si layer.

FIG. 10 (a) and (b) are schematic cross-sectional views of a heterojunction-containing TFT 801 and a homojunction-containing TFT 802, respectively, that were used for measurement.

FIG. 11 A diagram showing C-V characteristics of the heterojunction-containing TFT 801 and the homojunction-containing TFT 802.

FIG. 12 A diagram showing an energy band structure near a junction interface between a poly-Si layer and an n⁺ type Si layer.

### DESCRIPTION OF EMBODIMENTS

The inventors have studied various structures in order to improve channel mobility of TFTs, and found that a high channel mobility is obtained in a TFT having an interface at which a polysilicon layer (poly-Si layer) and an intrinsic amorphous silicon layer (i type a-Si layer) forms a junction. As will be described later, it is considered that the poly-Si layer and the i type a-Si layer have formed a heterojunction and that a two-dimensional electron gas (hereinafter “2DEG”) has been generated, as in a high-electron mobility transistor (HEMT).

2DEG refers to, when a junction is formed between two kinds of semiconductors of different band gap energies, a layer of electrons (i.e., a two-dimensional distribution of electrons) that is created at that interface (in a region which is about 10 nm thick near the interface). 2DEG is known to be composed of a compound semiconductor that may be GaAs-based, InP-based, GaN-based, SiGe-based, etc. However, it has not been known that 2DEG can ever occur at a junction interface between a poly-Si layer and any other semiconductor layer (e.g., an i type a-Si layer) having a band gap energy larger than that of poly-Si.

In the present specification, a junction between two semiconductor layers of different band gap energies (e.g., a junction between an i type a-Si layer and a poly-Si layer) is referred to a “semiconductor heterojunction”, and a junction between two semiconductor layers of similar band gap energies (e.g., a junction between an i type a-Si layer and an n⁺ type a-Si layer) is referred to as a “semiconductor homojunction”.

FIGS. 9(a) and (b) are schematic diagrams for describing an example of an energy band structure near the interface of a semiconductor heterojunction. This illustrates a semiconductor heterojunction that is created, in a polycrystalline silicon TFT of bottom-gate type, by disposing an i type a-Si layer on a non-doped poly-Si layer (active layer). FIG. 9(a) illustrates an energy band structure in the case where no gate voltage is applied, and FIG. 9(b) illustrates an energy band structure in the case where a positive voltage is applied to a gate electrode (not shown).

The poly-Si layer has a band gap energy Eg1 of about 1.1 eV, whereas the i type a-Si layer has a band gap energy Eg2 of about 1.88 eV. A depletion layer is formed at the poly-Si layer side. In FIG. 9(a), a flow of electrons is indicated by arrow 91, whereas a flow of holes is indicated by arrow 92. It is considered that, as shown in the figure, a quantum well qw is created at an interface between the i type a-Si layer and the poly-Si layer, in which electrons accumulate to generate 2DEG.

When a positive voltage is applied to the gate electrode (not shown), as illustrated by a broken line in FIG. 9(b), the energy band is bent by the electric field. As a result, at the semiconductor heterojunction interface, for example, an energy level Ec at the lower end of the conductor becomes lower than the Fermi level Ef (Ec<Ef). This causes the electron density at the quantum well qw to be higher, and thus the high-density electron layer (2DEG) contributes to electron conduction.

The region where 2DEG has been generated (hereinafter referred to as a “2DEG region”) can have a higher mobility than that of the poly-Si layer. Therefore, by creating a semiconductor heterojunction in a channel section of the TFT so that a high-mobility 2DEG region emerges, it becomes possible to enhance the channel mobility of the TFT. In the present specification, the mobility of a portion of the active layer of a TFT to become the channel is referred to as the “channel mobility”, as distinguished from the mobility of the material of the active layer itself.

In order for the 2DEG region to contribute to the improvement of the channel mobility of the TFT, the poly-Si layer in the semiconductor heterojunction needs to be located closer to the gate electrode than is the i type a-Si layer. Moreover, in order to generate a quantum well qw at the interface of the semiconductor heterojunction, it is preferable that a polysilicon layer that does not contain any conductivity type-imparting impurity (i.e., non-doped) is used as the poly-Si layer. Note that the Fermi levels of the poly-Si layer and the i type a-Si layer prior to junction may be of any relationship that allows the aforementioned quantum well qw to emerge as a result of the junction; the poly-Si layer may contain an impurity so long as this relationship is satisfied.

In the above description, a junction interface between an i type a-Si layer and a poly-Si layer was taken as an example; however, a similar 2DEG region may also occur at a junction interface between any layer of intrinsic semiconductor other than a-Si (i type semiconductor layer) and a poly-Si layer. The i type semiconductor layer may at least have a Fermi level (pre-junction Fermi level) such that the aforementioned quantum well qw will be created near the junction interface with the poly-Si layer, and may be a layer of wide band gap semiconductor, such as an intrinsic oxide semiconductor (e.g., an In—Ga—Zn—O-based semiconductor).

Next, a capacitance measurement which was conducted by the inventors in order to confirm an occurrence of 2DEG at the interface of a semiconductor heterojunction will be described.

FIGS. 10(a) and (b) are schematic cross-sectional views of ES-type TFTs 801 and 802, respectively, that were used in the capacitance measurement. The TFT 801 is a TFT having a semiconductor heterojunction between the gate and the source/drain (referred to as a “heterojunction-containing TFT”), whereas the TFT 802 is a TFT having a semiconductor homojunction between the gate and the source/drain (referred to as a “homojunction-containing TFT”).

The heterojunction-containing TFT 801 includes: a gate electrode 2 formed on a substrate; a gate insulating layer 3 covering the gate electrode 2; a semiconductor layer (active layer) 4 formed on the gate insulating layer 3; a protective insulating layer (etch stop layer) 5 covering a channel region of the semiconductor layer 4; and a source electrode 8s and a drain electrode 8d. The semiconductor layer 4 is a polysilicon layer (poly-Si layer). Between the semiconductor layer 4 and protective insulating layer 5 and the source electrode 8s, and between the semiconductor layer 4 and protective insulating layer 5 and the drain electrode 8d, an i type a-Si layer 6 composed of an intrinsic amorphous silicon and an n⁺ type a-Si layer 7 composed of n⁺ type amorphous silicon are disposed in this order as contact layers. The i type a-Si layer 6 and the semiconductor layer 4 are directly in contact. The junction g1 between the semiconductor layer 4, which is a poly-Si layer, and the i type a-Si layer 6 is a semiconductor heterojunction.

On the other hand, the homojunction-containing TFT 802 is similar in configuration to the heterojunction-containing TFT 801, except that an amorphous silicon layer (a-Si layer) is used as the semiconductor layer 4 and that an n⁺ type a-Si layer 7 is used as the only contact layer. The junction g2 between the semiconductor layer 4, which is an a-Si layer, and the n⁺ type a-Si layer 7 is a semiconductor homojunction.

By using a TFT monitor and applying an AC current (10 kHz) between the gate and the source, measurements of a capacitance C between the gate and the source were taken for the heterojunction-containing TFT 801 and the homojunction-containing TFT 802.

FIG. 11 is a diagram showing C-V characteristics of the heterojunction-containing TFT 801 and the homojunction-containing TFT 802, where the vertical axis represents capacitance C and the horizontal axis represents gate voltage Vg.

From FIG. 11, it can be seen that there is a smaller change in the capacitance of the heterojunction-containing TFT 801 than there is for the homojunction-containing TFT 802. This is indicative of a difference in carrier concentration (electrons). It is generally known that, as the carrier concentration increases, a semiconductor more closely resembles a metal, thus resulting in a smaller change in capacitance. In the heterojunction-containing TFT 801, electrons are considered to accumulate in the quantum well qw, which is formed at the interface of the junction g1 to cause 2DEG, thus making the carrier concentration correspondingly greater (i.e., because of the electrons distribution in the 2DEG) than that of the homojunction-containing TFT 802. One can confirm from this that 2DEG has been generated at the interface of the semiconductor heterojunction. Note that when a positive voltage is applied as the gate voltage Vg, the electrons having accumulated in the quantum well qw at the interface of the junction g1 are presumably discharged toward the semiconductor layer 4 in the heterojunction-containing TFT 801, thus resulting in a carrier concentration which is similar to that of the homojunction-containing TFT 802.

Hereinafter, with reference to the drawings, embodiments of the present invention will be described specifically.

### First Embodiment

A thin film transistor (TFT) according to a first embodiment is a polycrystalline silicon TFT of etchstop (ES) type. The TFT of the present embodiment is applicable to circuit boards for active matrix substrates or the like, various display apparatuses such as liquid crystal display apparatuses and organic EL display apparatuses, image sensors, electronic appliances, and so on.

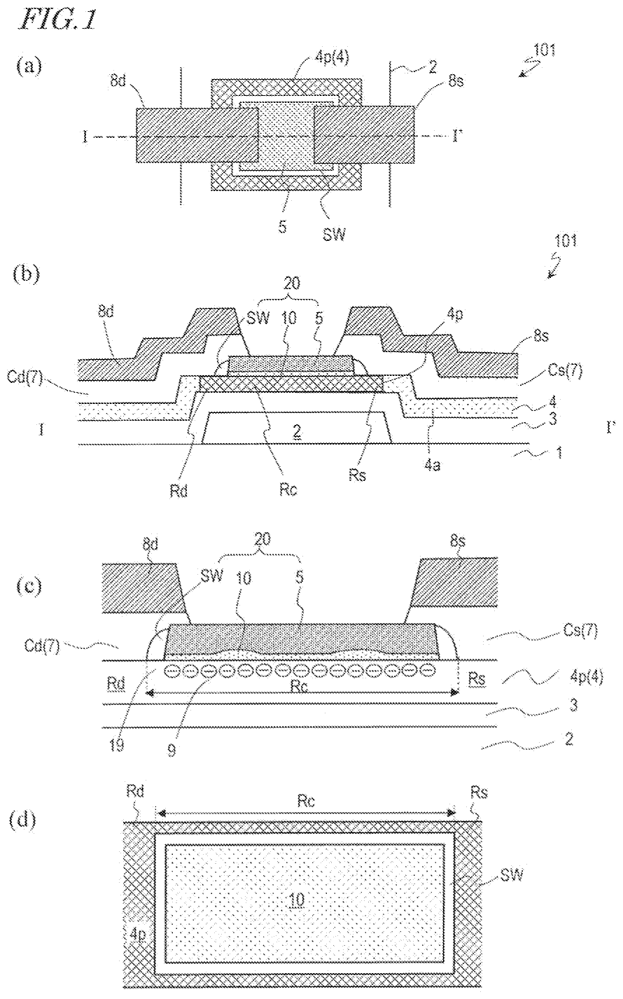

FIG. 1(a) is a schematic plan view of a thin film transistor (TFT) 101 according to the present embodiment, and FIG. 1(b) is a cross-sectional view of the TFT 101 taken along line I-I′. FIG. 1(c) is an enlarged cross-sectional view of a channel section of the TFT 101.

The TFT 101 is supported on a substrate 1 such as a glass substrate, and includes: a gate electrode 2; a gate insulating layer 3 covering the gate electrode 2; a semiconductor layer (active layer) 4 disposed on the gate insulating layer 3; and a source electrode 8s and a drain electrode 8d electrically connected to the semiconductor layer 4. Between the semiconductor layer 4 and the source electrode 8s and drain electrode 8d, a protecting section 20 that includes a protective insulating layer (also referred to as an etch stop layer) 5 is disposed.

The semiconductor layer 4, which layer functions as an active layer of the TFT 101, includes a polysilicon region (poly-Si region) 4p. As shown in the figure, the semiconductor layer 4 may include a poly-Si region 4p and an amorphous silicon region (a-Si region) 4a that mainly contains an amorphous silicon. Alternatively, the entire semiconductor layer 4 may be the poly-Si region 4p.

The poly-Si region 4p includes: a first region Rs and a second region Rd; and a channel region Rc which is located between them and in which a channel of the TET 101 is formed. The channel region Rc is disposed so as to overlap the gate electrode 2 via the gate insulating layer 3. The first region Rs is electrically connected to the source electrode 8s, whereas the second region Rd is electrically connected to the drain electrode 8d.

The protective insulating layer 5 is disposed so as to overlap a portion of the channel region Rc when viewed from the normal direction of the substrate 1. The protective insulating layer 5 is an insulating layer that is island-shaped, for example. Between the protective insulating layer 5 and the semiconductor layer 4, an i type a-Si layer 10 which is made of an amorphous silicon that contains substantially no impurity (i.e., intrinsic) is disposed. The i type a-Si layer 10 is directly in contact with a portion of the upper face of the channel region Rc. The thickness of the i type a-Si layer may be smaller than the thickness of the protective insulating layer 5.

On a side surface of the protective insulating layer 5, a sidewall SW is provided. The sidewall SW is made of an insulating film such as a silicon oxide film, for example. At least a portion of the bottom surface of the sidewall SW is directly in contact with the poly-Si region 4p (channel region Rc).

The i type a-Si layer 10 may have been patterned by using the same mask as that for the protective insulating layer 5. In that case, the side surface of the i type a-Si layer 10 is aligned with the side surface of the protective insulating layer 5. Moreover, the sidewall SW may be disposed so as to be directly in contact with both of the side surface of the protective insulating layer 5 and the side surface of the i type a-Si layer 10.

In the present specification, a structural body 20 that is composed of the protective insulating layer 5, the sidewall SW, and the i type a-Si layer 10 is referred to as the “protecting section”. The protecting section 20 is disposed so as to cover the channel region Rc of the semiconductor layer 4 and not to cover the first region Rs and the second region Rd.

FIG. 1(d) is an enlarged plan view illustrating an arrangement of the i type a-Si layer 10 and the sidewall SW in the protecting section 20. As shown in the figure, when viewed from the normal direction of the substrate 1, the i type a-Si layer 10 is disposed between the first region Rs and the second region Rd, so as to be spaced apart from the first region Rs and the second region Rd. Between the i type a-Si layer 10 and the first region Rs, and between the i type a-Si layer 10 and the second region Rd, the sidewall SW is directly in contact with the poly-Si region 4p (channel region Rc). When viewed from the normal direction of the substrate 1, the i type a-Si layer 10 may be surrounded by the sidewall SW.

In the present embodiment, as shown in FIG. 1(c), at a junction interface between the i type a-Si layer 10 in the protecting section 20 and the poly-Si region 4p of the semiconductor layer 4, a 2DEG region 9 is formed in which a two-dimensional electron gas (2DEG) that has been described above with reference to FIG. 9 is to occur. The 2DEG region 9 is a high-mobility region that may have a mobility equal to or greater than twice that of poly-Si, for example.

On the other hand, the sidewall SW in the protecting section 20 is an insulating layer such as a silicon oxide layer. At the junction interface between the sidewall SW and the poly-Si region 4p, no 2DEG is generated. In the present specification, a region 19 which is located at the junction interface between the poly-Si region 4p and the sidewall SW and in which no 2DEG is generated is referred to as the “non-2DEG region”. When viewed from the normal direction of the substrate 1, the non-2DEG region 19 is located between the 2DEG region 9 and the first region Rs and second region Rd. The non-2DEG region 19 may surround the 2DEG region 9. The non-2DEG region 19 isolates the 2DEG region 9 from the first region Rs and second region Rd, thereby preventing electrical conduction from being established between the source electrode 8s and the drain electrode 8d via the 2DEG region 9.

In the channel region Rc, at least the portion(s) of the poly-Si region 4p that is in contact with the i type a-Si layer 10 is preferably a polysilicon region that is non-doped (i.e., formed without intentional addition of an n type impurity). This allows the 2DEG region 9 to be formed at the junction interface between the poly-Si region 4p and the i type a-Si layer 10 with greater certainty.

Between the semiconductor layer 4 and protective insulating layer 5 and the source electrode 8s, a first contact layer Cs may be provided; and between the semiconductor layer 4 and protective insulating layer 5 and the drain electrode 8d, a second contact layer Cd may be provided. The source electrode 8s is electrically connected to the first region Rs of the semiconductor layer 4 via the first contact layer Cs. The drain electrode 8d is electrically connected to the second region Rd of the semiconductor layer 4 via the second contact layer Cd.

The first contact layer Cs and the second contact layer Cd include an impurity-containing silicon layer (which may be an a-Si layer or a poly-Si layer) that contains a conductivity type-imparting impurity. The impurity-containing silicon layers in the first contact layer Cs and the second contact layer Cd are spaced apart from each other. In this example, the impurity-containing silicon layers are n⁺ type a-Si layers 7 to which an n type-imparting impurity has been added. The n⁺ type a-Si layer 7 in the first contact layer Cs may be directly in contact with the first region Rs, whereas the n⁺ type a-Si layer 7 in the second contact layer Cd may be directly in contact with the second region Rd.

The first contact layer Cs and the second contact layer Cd may have a single-layer structure, or a multilayer structure. Although not shown, the first contact layer Cs and the second contact layer Cd may have a multilayer structure having the n⁺ type a-Si layer 7 as the lowermost layer. Alternatively, it may have a multilayer structure having the i type a-Si layer as a lower layer and the n⁺ type a-Si layer 7 as an upper layer.

In the example shown in FIG. 1, the impurity-containing silicon layers in the first contact layer Cs and the second contact layer Cd (which herein are n⁺ type a-Si layers 7) are disposed so as to be in contact with the first region Rs and the second region Rd, respectively, of the semiconductor layer 4. With this configuration, as can be seen from the energy band structure (see FIG. 12) near the junction interface between the n⁺ type a-Si layer and the poly-Si layer, electrons are unlikely to accumulate at the junction portion between the first region Rs and second region Rd and the n⁺ type a-Si layer 7, thus hindering generation of 2DEG; as a result, a gate-induced drain leakage current (GIDL) ascribable to 2DEG can be restrained from being generated.

In the TFT 101 of the present embodiment, the 2DEG region 9 having a higher mobility than that of the poly-Si region 4p is disposed in the channel region Rc. This allows the channel mobility of the TFT 101 to be improved, and enhances the ON current. Moreover, because of the non-2DEG region 19 being formed at the junction interface between the sidewall SW and the semiconductor layer 4, the 2DEG region 9 is isolated from both of the first region Rs and the second region Rd, and the 2DEG region 9 is not disposed so as to bridge between the source and the drain. This restrains the 2DEG region 9 from causing an increase in the off-leak current, or establishing electrical conduction between the source and the drain, thereby ensuring OFF characteristics. Thus, according to the present embodiment, it becomes possible to enhance the ON characteristics while maintaining the OFF characteristics; as a result, the ON/OFF ratio can be improved.

Furthermore, in the present embodiment, the channel mobility of the TFT 101 can be controlled by utilizing the 2DEG region 9, so that variations in the characteristics associated with variation in the crystal grain sizes of the poly-Si region 4p can be suppressed. As a result, reliability of the TFT 101 can be improved.

The channel region Rc includes a portion which is in contact with the i type a-Si layer 10 (a portion in which the 2DEG region 9 is formed) and a portion which is in contact with the sidewall SW (a portion to become the non-2DEG region 19). The channel region Rc may further include a portion that is in contact with neither the i type a-Si layer 10 nor the sidewall SW. When viewed from the normal direction of the substrate 1, a ratio AR of the total area of portions of the channel region Rc that are in contact with the i type a-Si layer 10 to the area of the entire channel region Rc may be not less than 50% and not more than 90%, for example. When it is not less than 50%, channel mobility can be enhanced more effectively. When the ratio AR is not more than 90%, increase in the off-leak current can be suppressed with greater certainty.

The structure of the protecting section 20 is not limited to the example shown in FIG. 1. For example, the side surfaces of the protective insulating layer 5 and the i type a-Si layer 10 do not need to be aligned. In the case where the protective insulating layer 5 and the i type a-Si layer 10 have different etching rates, or in the case where the protective insulating layer 5 and the i type a-Si layer 10 are to be patterned separately, the side surface of the i type a-Si layer 10 may be located inwardly or outwardly of the side surface of the protective insulating layer 5. Even in such cases, the sidewall SW may be formed so as to be in contact with the poly-Si region 4p at the source side and the drain side of the i type a-Si layer 10, whereby effects similar to those in FIG. 1 can be obtained.

Although the protective insulating layer 5 and the i type a-Si layer 10 are shown to be island-shaped in FIG. 1, these may not be island-shaped.

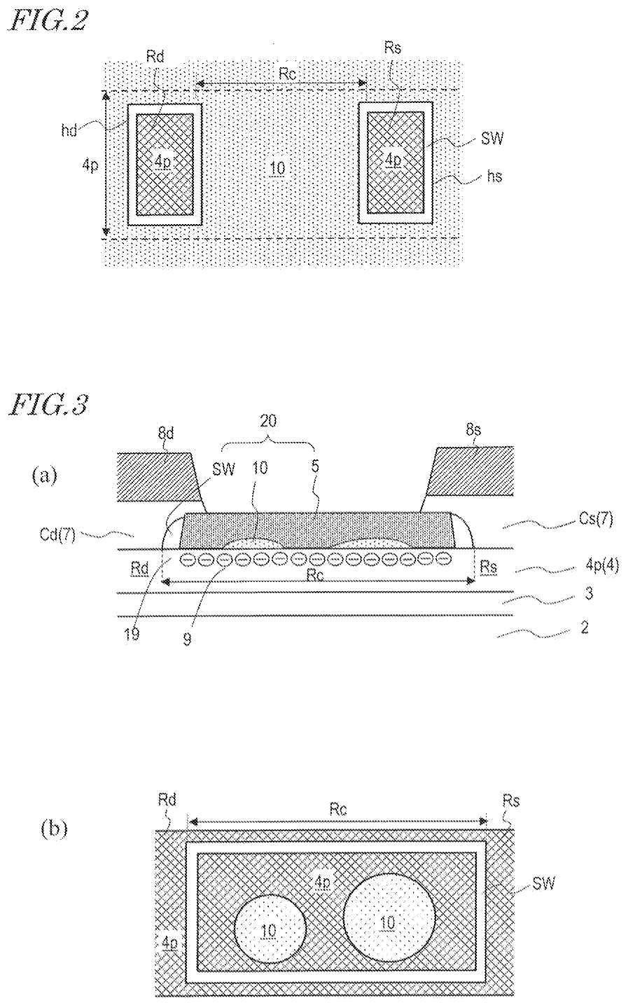

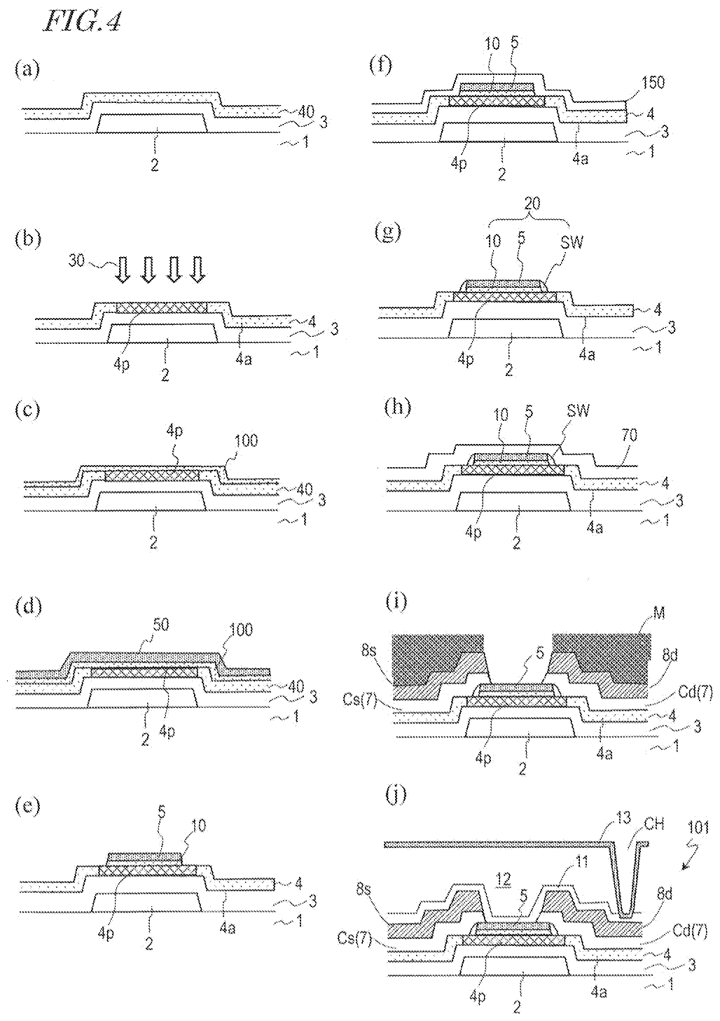

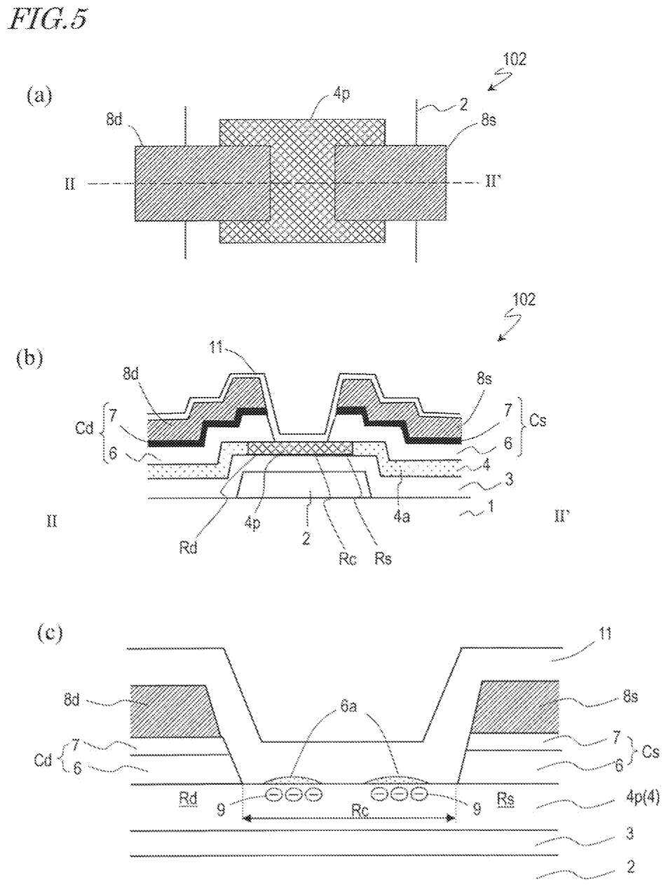

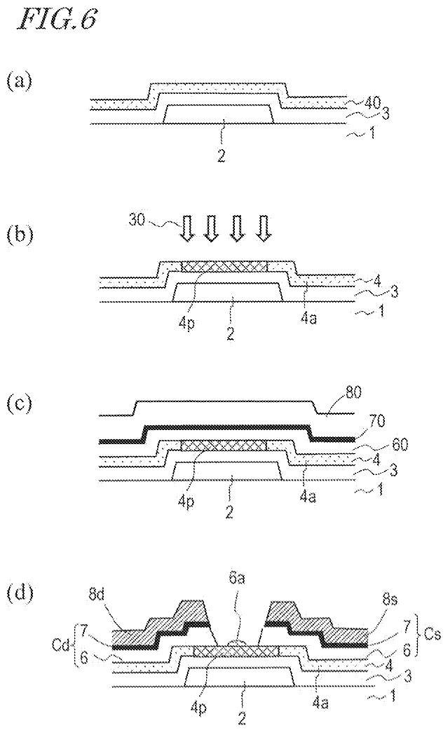

FIG. 2 is an enlarged plan view showing another exemplary arrangement of the i type a-Si layer 10 and the sidewall SW in the protecting section 20. As illustrated in FIG. 2, the protective insulating layer 5 (not shown) and the i type a-Si layer 10 may have apertures hs and hd through which the first region Rs and the second region Rd of the semiconductor layer 4 are exposed, and the sidewall SW may be formed on the side surfaces of the apertures hs and hd.

Furthermore, the example shown in FIG. 1 illustrates that the i type a-Si layer 10 is formed throughout the way between the protective insulating layer 5 and the semiconductor layer 4; alternatively, the i type a-Si layer 10 may have a structure (hereinafter “islanded structure”) including a plurality of i type a-Si islets that are disposed in a discrete manner.

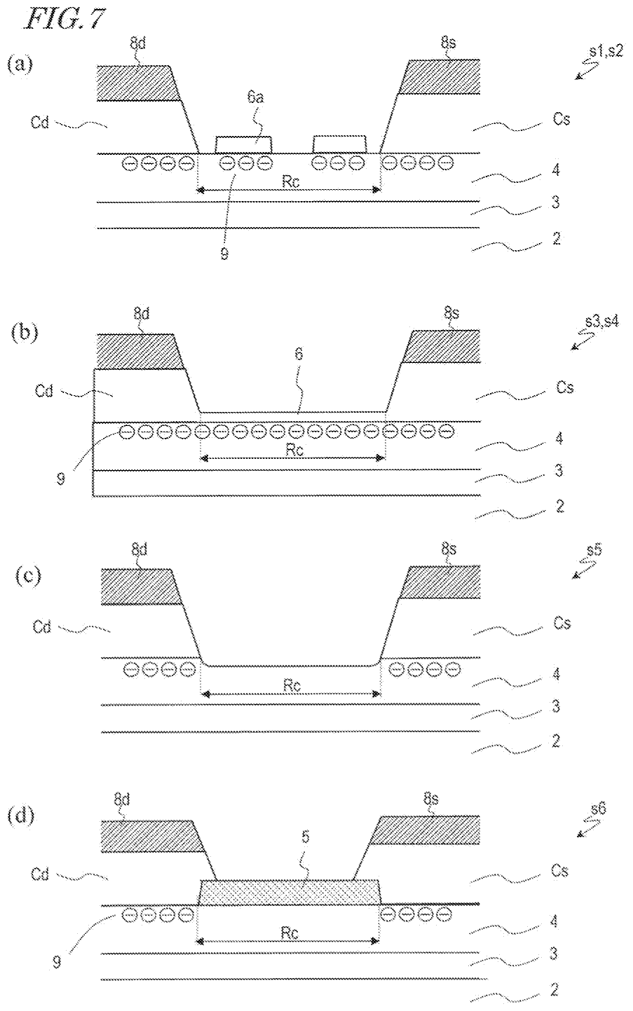

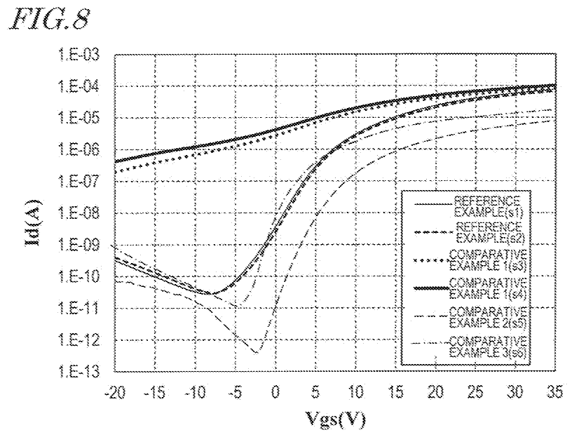

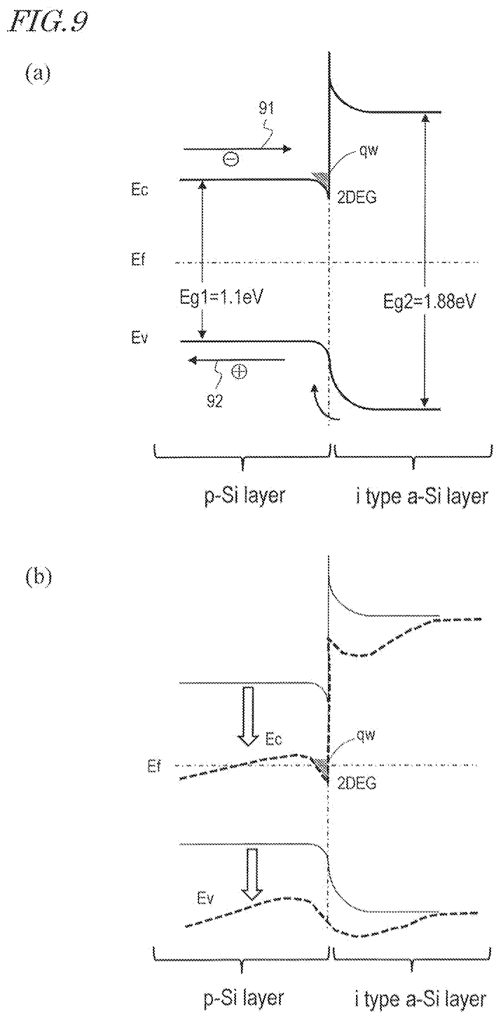

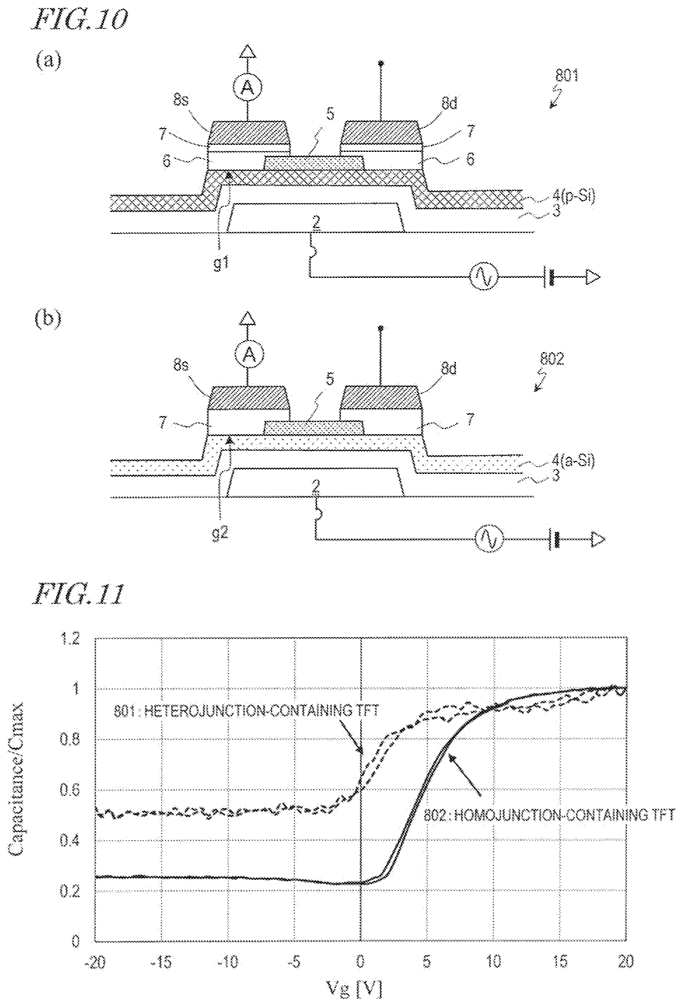

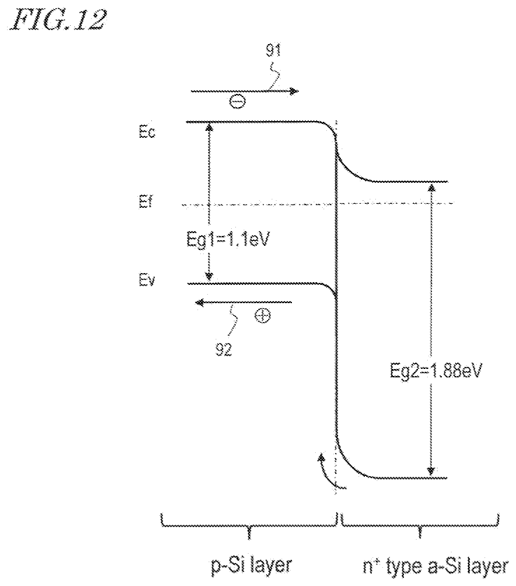

FIGS. 3(a) and (b) are a cross-sectional view and an enlarged view, respectively, illustrating another protecting section 20 according to the present embodiment.

In this example, an i type a-Si layer 10 having an islanded structure is disposed between the semiconductor layer 4 and the protective insulating layer 5. In other, words, one or more i type a-Si islets is/are formed between the protective insulating layer 5 and the semiconductor layer 4. As shown in the figure, a plurality of i type a-Si islets of mutually different sizes may be randomly disposed. For example, an initial phase of growth by the CVD (Chemical Vapor Deposition) technique may be utilized to form an intrinsic amorphous silicon film, whereby the i type a-Si layer 10 having an islanded structure as shown in the figure can be obtained. In this case, the aforementioned ratio AR may be not less than 20% and not more than 90%, and preferably not less than 50% and not more than 90%, for example. The area ratio AR can be adjusted by controlling conditions such as growth time.

The TFT 101 of the present embodiment can be suitably used for an active matrix substrate of a display apparatus or the like, for example. An active matrix substrate (or a display apparatus) has a displaying region that includes a plurality of pixels and a non-displaying region (also referred to as a peripheral region) other than the displaying region. For each pixel, a pixel TFT is provided as a switching element. In the peripheral region, gate drivers or other driving circuits may be monolithically formed. The driving circuits include a plurality of TFTs (“referred to as circuit TFTs”). The TFT 101 may be used as each pixel TFT and/or each circuit TFT.

The aforementioned active matrix substrate is suitably used for a liquid crystal display apparatus. For example, a counter substrate having a counter electrode and a color filter layer may be provided; the active matrix substrate and the counter substrate may be attached together via a sealant; and liquid crystal may be injected between these substrates, a liquid crystal display apparatus is obtained.

Without being limited to a liquid crystal display apparatus, any material of which optical property can be modulated or which can emit light upon voltage application may be used as a display medium layer, whereby various display apparatuses can be obtained. For example, the active matrix substrate according to the present embodiment can be suitably used for display apparatuses such as an organic EL display apparatus or an inorganic EL display apparatus in which an organic or inorganic phosphor material is used as a display medium layer. Furthermore, it can also be suitably used as an active matrix substrate for use in an X-ray sensor, a memory device, or the like.

### Method of Producing TFT 101

Next, an example of a method of producing the TFT 101 will be described.

FIG. 4(a) to FIG. 4(j) are schematic step-by-step cross-sectional views showing an example of a method of producing the TFT 101.

First, as shown in FIG. 4(a), on a substrate 1, a gate electrode 2, a gate insulating layer 3, and an a-Si film 40 for the active layer are formed in this order.

As the substrate 1, a substrate having a dielectric surface, e.g., a glass substrate, a silicon substrate, or a plastic substrate (resin substrate) having heat resistance, can be used.

The gate electrode 2 is formed by forming an electrically conductive film for the gate on the substrate 1, and patterning it. Herein, for example, an electrically conductive film for the gate (thickness: e.g. about 500 nm) is formed on the substrate 1 by sputtering, and the metal film is patterned by using a known photolithography process. For the etching of the gate electrically conductive film, wet etching may be used, for example.

The material of the gate electrode 2 may be: an elemental metal such as molybdenum (Mo), tungsten (W), copper (Cu), chromium (Cr), tantalum (Ta), aluminum (Al), or titanium (Ti); a material composed of these with nitrogen, oxygen, or other metals contained therein; or a transparent electrically conductive material such as indium tin oxide (ITO).

The gate insulating layer 3 is formed on the substrate 1 having the gate electrode 2 formed thereon, by a plasma CVD technique, for example. As the gate insulating layer (thickness: e.g. about 0.4 μm) 3, for example, a silicon oxide (SiO₂) layer, a silicon nitride (SiNx) layer, or a multilayer film of an SiO₂ layer(s) and an SiNx layer(s) may be formed.

The a-Si film 40 for the active layer may be formed by a CVD technique by using a hydrogen gas (H₂) and a silane gas (SiH₄), for example. The a-Si film 40 for the active layer may be a non-doped amorphous silicon film that substantially does not contain any n type impurity. A non-doped amorphous silicon film is an a-Si film which is formed without intentional addition of an n type impurity (e.g. by using a material gas that does not contain any n type impurity). Note that the a-Si film 40 for the active layer may contain an n type impurity at a relatively low concentration. The thickness of the a-Si film 40 for the active layer may be not less than 20 nm and not more than 70 nm (e.g. 50 nm).

Next, as shown in FIG. 4(b), within the a-Si film 40 for the active layer, at least a portion to become the channel region of the TFT is irradiated with laser light 30. As the laser light 30, ultraviolet laser such as XeCl excimer laser (wavelength 308 nm), or solid laser of a wavelength or 550 nm or less, such as a second harmonic (wavelength 532 nm) of YAG laser, may be used. Through irradiation of laser light 30, the region of the a-Si film 40 for the active layer that is irradiated with the laser light 30 melts and solidifies, whereby a poly-Si region 4p is formed. Thus, a semiconductor layer 4 including the poly-Si region 4p is obtained. In the poly-Si region 4p, crystal grains have grown in columnar shapes toward the upper face of the semiconductor layer 4.

There is no particular limitation as to the crystallization method using laser light 30. For example, laser light 30 from a laser light source may be passed through a microlens array so that the laser light 30 is converged onto only a portion of the a-Si film 40 for the active layer, thereby partly crystallizing the a-Si film 40 for the active layer. In the present specification, this crystallization method is referred to as “local laser annealing”. By using local laser annealing, as compared to the conventional laser annealing where the entire surface a-Si film is scanned with linear laser light, the time required for crystallization can be greatly reduced, whereby mass producibility can be promoted.

The microlens array includes a two-dimensional or linear arrangement of microlenses. When a plurality of TFTs are formed on the substrate 1, the laser light 30 is converged by the microlens array so as to be incident, within the a-Si film 40 for the active layer, only on a plurality of predetermined regions (irradiation regions) which are spaced apart from one another. Each irradiation region is disposed correspondingly to the portion of a TFT to become the channel region. The positions, number, shapes, sizes, etc., of irradiation regions can be controlled by the size and the array pitch of the microlens array (which is not limited to lenses under 1 mm), the opening positions in a mask that is disposed on the light source side of the microlens array, and the like. As a result, each region of the a-Si film 40 for the active layer that has been irradiated with the laser light 30 is heated to melt and solidify, thus becoming the poly-Si region 4p. Any region that has not been irradiated with the laser light remains as the a-Si region 4a. When viewed from the normal direction of the substrate 1, the a-Si region 4a may be disposed outside the poly-Si region 4p, for example.

As to the more specific method of local laser annealing, the configuration (including the microlens array, mask structure) of the apparatus used for local laser annealing, the entire disclosure of International Publication No. 2011/055618, International Publication No. 2011/132559, International Publication No. 2016/157351, and International. Publication No. 2016/170571 is incorporated herein by reference.

Next, as shown in FIG. 4(c), on the a-Si film 40 for the active layer, an i type a-Si film (referred to as an “a-Si film for 2DEG generation”) 100 is formed. The a-Si film for 2DEG generation 100 is formed by a CVD technique, for example. The thickness of the a-Si film for 2DEG generation 100 may be not less than 5 nm and not more than 50 nm (e.g. 20 nm) for example. When it is not less than 5 nm, a 2DEG region can be created between the a-Si film for 2DEG generation 100 and the poly-Si region 4p with greater certainty.

The a-Si film for 2DEG generation 100 can be formed by utilizing an initial phase of growth by the CVD technique. This allows a thin a-Si film for 2DEG generation 100 to be easily formed as desired. Although not particularly limited, the deposition time for the a-Si film for 2DEG generation 100 by the CVD technique may be not less than 2 seconds and not more than 150 seconds, for example.

Moreover, by controlling film formation conditions such as deposition time, an a-Si film for 2DEG generation (thickness: e.g. not less than 2 nm and not more than 5 nm) 100 having an islanded structure may be formed (see FIG. 3), for example. Herein, although not particularly limited, the deposition time may be not less than 0.2 seconds and not more than 1.0 seconds, for example. When it is not more than 1.0 seconds, the a-Si film for 2DEG generation 100 can be deposited in an island shape(s) with greater certainty. When it is not less than 0.2 seconds, the 2DEG region 9 can be formed between the a-Si film for 2DEG generation 100 and the poly-Si region 4p with greater certainty. In the case of utilizing an initial phase of growth by the CVD technique to form the a-Si film for 2DEG generation 100 having an islanded structure, the size and the position at which each islet is formed, the number of them within one channel region Rc, etc. will be random. Therefore, the 2DEG region 9 will also be formed in a random manner.

Note that the method of forming the a-Si film for 2DEG generation 100 is not limited to the CVD technique, but other known methods may also be used.

Next, as shown in FIG. 4(d), a protective insulating film 50 to become a protective insulating layer (etch stop layer) is formed on the semiconductor layer 4. Herein, as the protective insulating film 50, a silicon oxide film (SiO₂ film) is formed by the CVD technique. The thickness of the protective insulating film 50 may be not less than 30 nm and not more than 300 nm, for example. Thereafter, although not shown, the semiconductor layer 4 may be subjected to a dehydrogenation annealing treatment (e.g. 450° C., 60 minutes).

Then, as shown in FIG. 4(e), by using a resist mask (not shown), the protective insulating film 50 and the a-Si film for 2DEG generation 100 are patterned, thereby providing a protective insulating layer 5 and an i type a-Si layer 10 partially covering the portion of the semiconductor layer 4 to become the channel region. At the source side and the drain side of the portion to become the channel region, portions of the poly-Si region 4p are exposed from the protective insulating layer 5.

Next, as shown in FIG. 4(f), an insulating film 150 for forming the sidewall is formed so as to cover the semiconductor layer 4, the i type a-Si layer 10, and the protective insulating layer 5. Herein, by the CVD technique, a silicon oxide film (thickness: e.g. 0.1 μm) is formed.

Thereafter, as shown in FIG. 4(g), across the entire surface of the substrate 1, an anisotropic etching such as reactive ion etching (RIE) is performed. As a result of this, from the insulating film 150, a sidewall (also referred to as a “side-wall insulating film”, “sidewall spacer”) SW is formed on the side surfaces of the protective insulating layer 5 and the i type a-Si layer 10. The width of the sidewall SW along the channel length direction may be not less than 30 nm and not more than 90 nm, for example.

In this manner, a protecting section 20 that includes the protective insulating layer 5, the i type a-Si layer 10, and the sidewall SW is obtained. The portion of the semiconductor layer 4 that is in contact with the protecting section 20 becomes the channel region 11c, whereas the portions of the semiconductor layer 4 that are exposed from the protecting section 20 become a first region and a second region to be connected to the contact layers Cs and Cd.

Next, as shown in FIG. 4(h), an Si film for the contact layers is formed so as to cover the semiconductor layer 4 and the protecting section 20. Herein, as the Si film for the contact layers, an n⁺ type a-Si film (thickness: e.g. about 0.05 μm) 70 that contains an n type impurity (which herein is phosphorus) is deposited by the plasma CVD technique. As the material gas, a gaseous mixture of silane, hydrogen, and phosphine (PH₃) is used.

Alternatively, as the Si film for the contact layers, by the plasma CVD technique, a multilayer film including an i type a-Si film (thickness: e.g. about 0.1 μm) and an n⁺ type a-Si film (thickness: e.g. about 0.05 μm) that contains an n type impurity (e.g. phosphorus) may be formed. As the material gases for the i type a-Si film, a hydrogen gas and a silane gas are used. As the material gas for the n⁺ type a-Si film, a gaseous mixture of silane, hydrogen, and phosphine (PH₃) is used. The concentration of the n type impurity in the n⁺ type a-Si film is not less than 1×10¹⁸ cm⁻³ and not more than 5×10²⁰ cm⁻³, for example.

Next, on the Si film for the contact layers (which herein is an n⁺ type a-Si film 70), an electrically conductive film for the source and the drain electrode (thickness: e.g. about 0.3 μm) and a resist mask M are formed. The electrically conductive film for the source and the drain electrode is formed with a material similar to that for the electrically conductive film for the gate, by a method similar to that used for the electrically conductive film for the gate.

Thereafter, by using the resist mask M, the electrically conductive film for the source and the drain electrode and the n⁺ type a-Si film 70 are patterned by dry etching, for example. As a result, as shown in FIG. 4(i), a source electrode 8s and a drain electrode 8d are formed from the electrically conductive film (source-drain separation step). Moreover, from the n⁺ type a-Si film 70, n⁺ type a-Si layers 7 to become a first contact layer Cs and a second contact layer Cd are formed so as to be spaced apart from each other. During the patterning, the protective insulating layer 5 functions as an etchstop, so that the portion of the semiconductor layer 4 that is covered by the protective insulating layer 5 is not etched. The ends of the first contact layer Cs and the second contact layer Cd that are closer to the channel are located on an upper face of the protective insulating layer 5. Thereafter, the resist mask M is removed off the substrate 1. Thus, the TFT 101 is produced.

In order to deactivate dangling bonds in the poly-Si region 4p and reduce the defect density, the poly-Si region 4p may be subjected to a hydrogen plasma treatment after the source-drain separation step.

In the case where the TFT 101 is used as a pixel TFT of an active matrix matrix substrate, as shown in FIG. 4(j), an interlayer insulating layer is formed so as to cover the TFT 101. Herein, as the interlayer insulating layer, an inorganic insulating layer (passivation film) 11 and an organic insulating layer 12 are formed.

As the inorganic insulating layer 11, a silicon oxide layer, a silicon nitride layer, or the like may be used. Herein, as the inorganic insulating layer 11, an SiNx layer (thickness: e.g. about 200 nm) is formed by the CVD technique, for example. The inorganic insulating layer 11 is in contact with the protective insulating layer 5 in (a gap) between the source electrode 8s and the drain electrode 8d.

The organic insulating layer 12 may be an organic insulating film (thickness: e.g. 1 to 3 μm) containing a photosensitive resin material, for example. Thereafter, the organic insulating layer 12 is patterned, and an aperture is formed therein. Next, by using the organic insulating layer 12 as a mask, the inorganic insulating layer 11 is etched (dry etching). As a result, a contact hole CH that reaches the drain electrode 8d is formed in the inorganic insulating layer 11 and the organic insulating layer 12.

Next, a transparent electrically conductive film is formed on the organic insulating layer 12 and in the contact hole CH. As the material for the transparent electrode film, a metal oxide such as indium-tin oxide (ITO), indium-zinc oxide, or ZnO can be used. Herein, by e.g. sputtering, an indium-zinc oxide film (thickness: e.g. about 100 nm) is formed as the transparent electrically conductive film.

Thereafter, the transparent electrically conductive film is patterned by e.g. wet etching, thereby providing a pixel electrode 13. The pixel electrode 13 is to be disposed so as to be each spaced apart, from pixel to pixel. Each pixel electrode 13 is in contact with the drain electrode 8d of the corresponding TFT within the contact hole. Although not illustrated, the source electrode 8s of the TFT 101 is electrically connected to a source bus line (not shown), while the gate electrode 2 is electrically connected to a gate bus line (not shown).

The semiconductor layer 4, the first contact layer Cs, and the second contact layer Cd may be patterned into island shapes in the region where the TFT 101 is formed (TFT formation region). Alternatively, the semiconductor layer 4, the first contact layer Cs, and the second contact layer Cd may extend to regions other than the region where the TFT 101 is formed (TFT formation region). For example, the semiconductor layer 4 may extend so as to overlap a source bus line that is connected to the source electrode 8s. It suffices if the portion of the semiconductor layer 4 that is located in the TFT formation region contains the poly-Si region 4p; the portion extending to regions other than the TFT formation region may be the a-Si region 4a.

Moreover, the crystallization method of the a-Si film 40 for the active layer is not limited to the aforementioned local laser annealing. A part or a whole of the a-Si film 40 for the active layer may be crystallized by using other known methods.

Furthermore, instead of the i type a-Si layer 10, a semiconductor layer type semiconductor layer) that is composed of any other intrinsic semiconductor (which may be amorphous or crystalline) may be used. The i type semiconductor layer has a greater band gap than that of the poly-Si region 4p, and forms a semiconductor heterojunction with the poly-Si region 4p. As the i type semiconductor layer, for example, a semiconductor layer composed of a wide band gap semiconductor such as an intrinsic oxide semiconductor (e.g. an In—Ga—Zn—0-based semiconductor) can be used. The i type semiconductor layer has a Fermi level (pre-junction Fermi level) such that the aforementioned quantum well qw is formed near the junction interface with the poly-Si region 4p. The i type semiconductor layer may be formed through a process similar to that for the i type a-Si layer 10, for example. The i type semiconductor layer may include a plurality of i type semiconductor islets that are disposed in a discrete manner (see FIG. 3).

In the case where an i type oxide semiconductor layer composed of an intrinsic oxide semiconductor is used as the i type semiconductor layer, the oxide semiconductor may be amorphous or crystalline. The crystalline oxide semiconductor may be a polycrystalline oxide semiconductor, a microcrystalline oxide semiconductor, a crystalline oxide semiconductor whose c axis is oriented essentially perpendicular to the layer plane, for example. The material, structure, method of film formation, etc., of an amorphous or crystalline oxide semiconductor are described in the specification of Japanese Patent No. 6275294, for example. The entire disclosure of the specification of Japanese Patent No. 6275294 is incorporated herein by reference.

### Embodiment for Reference

Hereinafter, a TFT according to Embodiment for Reference and experimental results indicating that TFT characteristics can be improved by utilizing the 2DEG region will be described.

The TFT according to Embodiment for Reference is a polycrystalline silicon TFT of channel-etch (CE) type.

FIG. 5(a) is a schematic plan view of a thin film transistor (TFT) 102 according to Embodiment for Reference, and FIG. 5(b) is a cross-sectional view of the TFT 102 as taken along line II-II′. FIG. 5(c) is an enlarged cross-sectional view of the channel section of the TFT 102. In FIG. 5, similar constituent elements to those in FIG. 1 are denoted by the same reference numerals. In the following description, description of any constituents similar to those of the TFT 101 shown in FIG. 1 may be omitted.

In the TFT 102, between a semiconductor layer 4 and a source electrode 8s and a drain electrode 8d, no protecting section that includes an etch stop layer covering the channel region Rc (as in the protecting section 20 shown in FIG. 1) is provided.

In the TFT 102, too, as shown in FIG. 5(c), at least one i type a-Si islet 6a is disposed on a poly-Si region 4p in the channel region Rc, and a 2DEG region 9 is formed between the i type a-Si islet(s) 6a and the poly-Si region 4p.

Between the source electrode 8s and the drain electrode 8d, an inorganic insulating layer 11 is directly in contact with the i type a-Si islet(s) 6a and the portion of the semiconductor layer 4 that is not covered by the i type a-Si islet(s) 6a. Otherwise, its structure may be similar to that of the TFT 101 shown in FIG. 1.

In this example, the first contact layer Cs and the second contact layer Cd may have a multilayer structure including an i type a-Si layer 6 directly in contact with the semiconductor layer 4 and an n⁺ type a-Si layer disposed on the i type a-Si layer 6, for example. In this manner, an i type a-Si islet(s) 6a can be formed by using the same silicon film as that for the i type a-Si layer 6. For example, in the source-drain separation step, etching may be performed under conditions such that the i type a-Si layer 6 will remain locally above the channel region Rc, thereby forming the i type a-Si islet(s) 6a. In this case, the i type a-Si islet(s) 6a will be thinner than the i type a-Si layers 6 of the first contact layer Cs and the second contact layer Cd. As shown in the figure, a plurality of i type a-Si islets 6a of different sizes may be randomly disposed on the channel region Rc.

FIGS. 6(a) to (d) are step-by-step cross-sectional views for describing an example method of producing the TFT 102. Hereinafter, differences from the above-described embodiment (FIG. 4) will mainly be described. Whenever the material, thickness, the method of forming, etc., of each layer are similar to those in the above-described embodiment, the description thereof may be omitted.

First, as shown in FIG. 6(a), a gate electrode 2, a gate insulating layer 3, and an a-Si film 40 for the active layer are formed on a substrate 1. Next, as shown in FIG. 6(b), the a-Si film 40 for the active layer is irradiated with laser light 30, thereby providing the semiconductor layer 4 including the poly-Si region 4p. As shown in the figure, a semiconductor layer 4 including the poly-Si region 4p and the a-Si region 4a may be formed by local laser annealing. These steps are similar to those in the above-described embodiment.

Next, as shown in FIG. 6(c), an Si film for the contact layers and an electrically conductive film 80 for the source and drain electrodes are formed in this order so as to cover the semiconductor layer 4. Herein, as the Si film for the contact layers, a multilayer film including an i type a-Si film (thickness: e.g. about 0.1 μm) 60 and an n⁺ type a-Si film (thickness: e.g. about 0.05 μm) 70 that contains an n type impurity (e.g. phosphorus) is formed by the plasma CVD technique. The phosphorus concentration in the n⁺ type a-Si film is not less than 1×10¹⁸ cm⁻³ and not more than 5×10²⁰ cm⁻³, for example. As the material gases for the i type a-Si film 60, a hydrogen gas and a silane gas are used. As the material gas for the n⁺ type a-Si film 70, a gaseous mixture of silane, hydrogen, and phosphine (PH₃) is used.

Next, as shown in FIG. 6(d), by using a resist mask (not shown), the i type a-Si film 60, the n⁺ type a-Si film 70, and the electrically conductive film 80 are patterned by e.g. dry etching (source-drain separation step). At this time, the patterning is performed under conditions such that the electrically conductive film 80 and the n⁺ type a-Si film 70 are completely removed in the region that is not covered by the resist mask (i.e., the region to become the channel region), and that the i type a-Si film 60 remains in an island shape(s) on the semiconductor layer 4. By adjusting the etching time, for example, it becomes possible to leave the i type a-Si layer 6 in an island shape(s) on the channel region. Through this patterning step, the first contact layer Cs and the second contact layer Cd are obtained from the i type a-Si film 60 and the n⁺ type a-Si film 70, and the source electrode 8s and the drain electrode 8d are obtained from the electrically conductive film 80. Moreover, the i type a-Si islet(s) 6a can be formed from the i type a-Si film 60.

Note that the aforementioned patterning may be conducted under conditions such that only the surface portion of the portion of the i type a-Si film 60 that is not covered by the resist mask is removed (i.e., thin-filmed). In this case, the thin-filmed i type a-Si film 60 may separately be patterned into island shapes to form the i type a-Si islets) 6a. Forming the i type a-Si islet(s) 6a through patterning allows the i type a-Si islet(s) 6a to be formed into a predetermined pattern. For example, the i type a-Si islets 6a may be disposed as shown in FIGS. 3(b) to (d).

Alternatively, after the source-drain separation step is performed, another i type a-Si film may be formed so as to cover the channel region and patterned to form the i type a-Si islet(s) 6a. In this case, it is not necessary to use the i type a-Si film 60 as an Si film for the contact layers. As a result, no 2DEG is generated between the contact layers Cs and Cd and the semiconductor layer 4, whereby a GIRL can be suppressed.

### Experimental Results

In order to confirm that it is possible to improve TFT characteristics by utilizing 2DEG, thin film transistors according to Reference Example and Comparative Examples were produced, and their TFT characteristics were measured; the methods and results thereof will now be described.

FIG. 7(a) is a schematic enlarged cross-sectional view of a thin film transistor according to Reference Example; and (b) to (d) are schematic enlarged cross-sectional views of thin film transistors according to Comparative Examples 1 to 3, respectively.

First, by the method described above with reference to FIG. 6, thin film transistors s1 and s2 according to Reference Example were produced. The thin film transistors s1 and s2 are similar in structure to what is shown in FIG. 5.

Next, by a similar method to that of Reference Example except for the etching condition (e.g. etching time)in the source-drain separation step, thin film transistors according to Comparative Examples 1 and 2 were produced. In Comparative Example 1, etching was performed under conditions such that, between the source electrode 8s and the drain electrode 8d, only the surface portion of the i type a-Si layer 6 was removed, and that the i type a-Si layer 6 remained so as to cover substantially the entire channel region Rc, thereby providing thin film transistors s3 and s4. In Comparative Example 2, etching was performed under conditions such that, between the source electrode 8s and the drain electrode 8d, the i type a-Si layer 6 was completely removed, and that the surface portion of the semiconductor layer 4 was overetched, thereby providing a thin film transistor s5.

Furthermore, in Comparative Example 3, a source-drain separation step was performed while the channel region Rc was covered with the protective insulating layer (SiO₂ layer) 5, thereby providing a thin film transistor s6 of ES-type. The protective insulating layer 5 and the channel region Rc are directly in contact, and no a-Si islets are provided between them.

Next, TFT characteristics of the thin film transistors s1 to s6 according to Reference Example and Comparative Examples 1 to 3 were evaluated.

FIG. 8 is a diagram showing V-I (gate voltage Vgs-drain current Id) characteristics of the thin film transistors according to Reference Example and Comparative Examples 1 to 3.

It can be seen from FIG. 8 that, in the thin film transistors s3 and s4 according to Comparative Example 1, electrical conduction is established between the source and the drain (punch-through), such that functionality of a switching element cannot be obtained. This is presumably because, at the interface between the semiconductor layer 4 and the i type a-Si layer 6, a high-mobility 2DEG region 9 was continuously formed throughout the way from the first region Rs, via the channel region Rc, to the second region Rd, thereby electrically connecting the source electrode 8s and the drain electrode 8d via the 2DEG region 9.

It can also be seen that the ON current the thin film transistor s5 according to Comparative Example 2 is lower than those of the thin film transistors s1 and s2 according to Reference Example. This is presumably because the i type a-Si layer 6 does not remain above the channel region and thus no 2DEG occurs, so that high-mobility effects due to 2DEG cannot be obtained.

Note that the ON current of the thin film transistor s5 according to Comparative Example 2 is lower than that of the thin film transistor s6 according to Comparative Example 3. The presumable reason for this is that, in the thin film transistor s5, the surface portion of the semiconductor layer 4 is overetched so that the polycrystalline silicon layer is considerably removed, most of which becoming a layer of small crystal grain sizes or an amorphous layer, or the channel section has become damaged or the semiconductor layer 4 has become varied in thickness, thus resulting in a lower ON current than that of the thin film transistor s6, in which the semiconductor layer 4 is protected at the surface.

On the other hand, the thin film transistors s1 and s2 according to Reference Example attain higher ON currents than those of the thin film transistor s5 according to Comparative Example 2 and the thin film transistor s6 according to Comparative Example 3. This is presumably because, in the thin film transistors s1 and s2 according to Reference Example, the high-mobility 2DEG region 9 is formed at the junction portion between the channel region Rc and the i type a-Si islet(s) 6a, thus resulting in a higher channel mobility of the TFT. Moreover, the portions of the channel region Rc that are not in contact with the i type a-Si islet 6a constitute a non-2DEG region in which 2DEG is not generated. This is presumably because a non-2DEG region exists in a portion of the channel region Rc to prevent the 2DEG region 9 from being formed throughout the way from the first region Rs to the second region Rd along the channel length direction (i.e., so as to bridge between the source and the drain), thereby suppressing a punch-through.

Thus, the results shown in FIG. 8 confirm that, by creating the 2DEG region 9 in the channel region Rc and by disposing a non-2DEG region so that the between the source and the drain will not be bridged via the 2DEG region 9, the ON current can be improved while maintaining the OFF characteristics.

Although CE-type TFTs were taken as examples of the thin film transistor according to Reference Example, an ES-type TFT according to the embodiment shown in FIG. 1 will provide similar effects to those of Reference Example.

The structure of a TFT according to the present invention is not limited to the structure described above with reference to FIG. 1. A TFT of an embodiment according to the present invention may have any structure that allows a semiconductor heterojunction to be formed in the channel section, such that the ON current can be enhanced by utilizing the 2DEG region 9 being created at this junction interface.

### INDUSTRIAL APPLICABILITY

Embodiments of the present invention are broadly applicable to apparatuses and electronic appliances that include TFTs, for example: circuit boards of active matrix substrates or the like; display apparatuses such as liquid crystal display apparatuses, organic electroluminescence (EL) display apparatus, and inorganic electroluminescence display apparatuses; imaging devices such as radiation detectors and image sensors; electronic devices such as image input devices and fingerprint reader devices, and the like.

### REFERENCE SIGNS LIST

1: substrate, 2: gate electrode, 3: gate insulating layer, 4: semiconductor layer, 4a: a-Si region, 4p: poly-Si region, 5: protective insulating layer, 7: n⁺ type a-Si layer, 8d: drain electrode, 8s: source electrode, 9: 2DEG region, 10: i type a-Si layer, 11: inorganic insulating layer, 12: organic insulating layer, 13: pixel electrode, 19: non-2DEG region, 20: protecting section, 30: laser light, 40: a-Si film for the active layer, 50: insulating film, 80: electrically conductive film, 100: a-Si film for 2DEG generation, Cs: first contact layer, Cd: second contact layer, M: resist mask, SW: sidewall, Rc: channel region, Rd: second region, Rs: first region

1. A thin film transistor comprising:
a substrate;
a gate electrode supported by the substrate;
a gate insulating layer covering the gate electrode;
a semiconductor layer being disposed on the gate insulating layer and including a polysilicon region, the polysilicon region including a first region, a second region, and a channel region that is located between the first region and the second region;
a source electrode electrically connected to the first region;
a drain electrode electrically connected to the second region; and
a protecting section disposed between the semiconductor layer and the source electrode and drain electrode, the protecting section covering the channel region but not covering the first region and the second region, wherein
the protecting section includes
at least one i type semiconductor layer composed of an intrinsic semiconductor, the at least one i type semiconductor layer being disposed directly in contact with a portion of the channel region,
a protective insulating layer disposed on the i type semiconductor layer, and
a sidewall disposed on a side surface of the protective insulating layer;
the i type semiconductor layer has a band gap larger than that of the polysilicon region; and,
when viewed from a normal direction of the substrate, the sidewall is directly in contact with the channel region, between the i type semiconductor layer and the first region and between the i type semiconductor layer and the second region.

2. The thin film transistor of claim 1, wherein, when viewed from the normal direction of the substrate, the sidewall surrounds the i type semiconductor layer.

3. The thin film transistor of claim 1, wherein the sidewall is disposed on the side surface of the protective insulating layer and a side surface of the i type semiconductor layer.

4. The thin film transistor of claim 1, wherein, when viewed from the normal direction of the substrate, a total area of portions of the channel region that are in contact with the i type semiconductor layer accounts for not less than 50% and not more than 90% of an area of the entire channel region.

5. The thin film transistor of claim 1, wherein the source electrode is connected to the first region of the semiconductor layer via a first contact layer, and the drain electrode is connected to the second region of the semiconductor layer via a second contact layer; and
the first and second contact layers each include an n⁺ type a-Si layer composed of an n⁺ type amorphous silicon.

6. The thin film transistor of claim 1, wherein the i type semiconductor layer has an islanded structure including a plurality of i type semiconductor islets disposed in a discrete manner.

7. The thin film transistor of claim 1, wherein, when viewed from the normal direction of the substrate, the semiconductor layer further includes an amorphous silicon region located outside the polysilicon region.

8. The thin film transistor of claim 1, wherein the i type semiconductor layer is an i type a-Si layer composed of an intrinsic amorphous silicon.

9. A display apparatus comprising the thin film transistor of claim 1, wherein
the display apparatus has a displaying region including a plurality of pixels; and
the thin film transistor is disposed in each of the plurality of pixels.

10. A method of producing a thin film transistor supported by a substrate, the method comprising:
a step of forming on the substrate a gate electrode, a gate insulating layer covering the gate electrode, and a semiconductor layer including a polysilicon region;
a step of forming on the semiconductor layer an i type semiconductor film and a protective insulating film in this order, the i type semiconductor film being composed of an intrinsic semiconductor, wherein the i type semiconductor film has a band gap larger than that of the polysilicon region;
a step of patterning the i type semiconductor film and the protective insulating film to form an i type semiconductor layer from the i type semiconductor film and to form a protective insulating layer from the protective insulating film, wherein the i type semiconductor layer and the protective insulating layer are located on a part of a portion of the semiconductor layer to become a channel channel region, and expose a first region and a second region that are located on opposite sides of the portion of the semiconductor layer to become the channel region;
a step of forming an insulating film covering the semiconductor layer, the i type semiconductor layer, and the protective insulating layer, and performing anisotropic etching to form a sidewall on a side surface of the protective insulating layer from the insulating film;
a step of forming a silicon film for contact layer formation and an electrically conductive film in this order, so as to cover the semiconductor layer, the i type semiconductor layer, the protective insulating layer, and the sidewall; and
an source-drain separation step of patterning the silicon film for contact layer formation and the electrically conductive film by using the protective insulating layer as an etchstop, to form from the silicon film for contact layer formation a first contact layer that is in contact with the first region and a second contact layer that is in contact with the second region, and to form from the electrically conductive film a source electrode that is in contact with the first contact layer and a drain electrode that is in contact with the second contact layer.

11. The method of producing a thin film transistor of claim 10, wherein the i type semiconductor film is formed by utilizing an initial phase of growth of film formation by a CVD technique.

12. The method of producing a thin film transistor of claim 11, wherein the i type semiconductor film has an islanded structure including a plurality of i type semiconductor islets disposed in a discrete manner.

13. The method of producing a thin film transistor of claim 10, wherein the i type semiconductor layer is an i type a-Si layer composed of an intrinsic amorphous silicon.

14. A method of producing a display apparatus comprising the thin film transistor of claim 1, wherein
the display apparatus has a displaying region including a plurality of pixels, the thin film transistor being disposed in each of the plurality of pixels of the displaying region;
the method of producing comprises a semiconductor layer forming step of forming the semiconductor layer of the thin film transistor; and
the semiconductor layer forming step comprises a crystallization step of irradiating only a portion of a semiconductor film that is formed on the gate insulating layer and composed of an amorphous silicon with laser light to crystallize the portion of the semiconductor film, wherein the polysilicon region is formed in the portion of the semiconductor film while leaving a portion of the semiconductor film that has not been irradiated with the laser light so as to remain amorphous.
